(19) United States
(12) Patent Application Publication
(10) Pub. No.: US 2008/0218276 A1
(43) Pub. Date: Sep. 11, 2008

(54) MEANS TO CONTROL PLL PHASE SLEW RATE

(75) Inventor: James Toner Sundby, Tracy, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Exar Corporation, Fremont, CA (US)

(21) Appl. No.: 11/681,886

(22) Filed: Mar. 5, 2007

(51) Int. Cl. H03L 7/00

(52) U.S. Cl. 331/17

(57) ABSTRACT

A charge pump includes a multitude of current sources and current sinks adapted to supply current to or discharge current from a loop filter. The paths between current sources/sinks and the loop filter are selectively activated or deactivated to enable current to flow from the current source(s) to the loop filter or flow from the loop filter to the current sinks(s). Accordingly, the charge pump is adapted to provide more than one bandwidth depending on the bit levels of a select signal. The slew rate of a PLL in which the charge pump is disposed may thus be reduced. The charge pump optionally includes pulse-width limiting circuitry to limit the width of the pulses received from a phase/frequency detector. Accordingly, the slew rate of the PLL may further be reduced without changes in the open loop characteristics or losses in the phase margin.

### BACKGROUND OF THE INVENTION

The present invention relates to electronic circuits, and more particularly to controlling the phase slew rate of a phased locked loop.

A phase locked loop maintains a fixed relationship between the phase and frequency of the signal it receives and those of the signal it generates. FIG. 1 is a simplified block diagram of a conventional phase locked loop (PLL) 10 adapted to maintain a fixed relationship between the phase and frequency of signal CLK and signal REF. PLL 10 includes, among other components, phase detector 12, charge pump 14, loop filter 16 and voltage controlled oscillator (VCO) 18. The extracted clock signal Clk is supplied at the output terminal of VCO 18. The operation of PLL 10 is described further below.

Phase detector 12 receives signals REF and Clk, and in response, generates signals UP and DN that correspond to the difference between the phases of the signals REF and Clk. Charge pump 14 receives signals UP and DN and in response varies the current it supplies to node N. Loop filter 16 stores the charge as a voltage, which is then delivered to VCO 18.

If signal REF leads signal Clk in phase—indicating that the VCO is running relatively slowly—the duration of pulse signal UP increases while the duration of pulse signal DN decreases, thereby causing charge pump 14 to increase its net output current I until VCO 18 achieves an oscillation frequency at which signal Clk is frequency-locked and phase-locked with signal REF. If, on the other hand, signal REF lags signal Clk in phase—indicating that the VCO is running relatively fast—the duration of pulse signal UP decreases while the duration of pulse signal DN increases—thereby causing VCO 18 achieve an oscillation frequency at which signal Clk is frequency-locked and phase-locked with signal REF. Signal Clk is considered to be locked to signal REF if its frequency is within a predetermined frequency range of signal REF. Signal Clk is considered to be out-of-lock with signal REF if its frequency is outside the predetermined frequency range of signal REF.

When the input reference clock to a PLL changes phase, the PLL must slew to the new phase. Such a condition may happen when, for example, the PLL switches from one reference clock to another clock with the same frequency but a different phase. Such a condition may also happen if the clock that the PLL switches to has a different frequency than the clock the PLL switches from. Furthermore, in some applications it is desirable to have the PLL output clock switch slowly, and not rapidly, to the new phase so as to enable other down-stream circuits to maintain proper operation.

To control the PLL's response time, in accordance with one prior art technique, the characteristics of an external filter used in the PLL is dynamically changed. For example, by lowering the resistance of a resistor used in the filter, the loop bandwidth may be lowered. FIG. 2 shows plots of the phase-frequency of a PLL for two different values of filter resistance, as known in the prior art. A lower resistance value is used in plot 200 relative to plot 100.

Referring to plot 100, the PLL has two poles at zero frequency. At frequency F₂, also referred to as open-loop zero, the PLL is shown as having a zero, therefore the slope of the response decreases from −40 dB/decade to −20 dB/decade. The 0-dB crossing occurs at frequency F₃. The PLL is shown as having another pole at frequency F₄, thus increasing the slope of the response from −20 dB/decade to −40 dB/decade. Referring to plot 200, the PLL has two poles at zero frequency. At frequency F′₂, also referred to as open-loop zero, the PLL is shown as having a zero, therefore the slope of the response decreases from −40 dB/decade to −20 dB/decade. The 0-dB crossing occurs at frequency F′₃. As is seen from FIG. 2, by lowering the resistance value, the open loop zero increases from F₂ to F′₂, while the 0-dB crossing decreases from F₃ to F′₃. In other words, by lowering the resistance value, the frequency spacing between the open-loop zero and 0-db crossing is reduced. This reduction results in lowering of the PLL's phase margin, thus contributing to the PLL's instability.

### BRIEF SUMMARY OF THE INVENTION

A charge pump, in accordance with one embodiment of the present invention, includes a multitude of current sources and current sinks adapted to supply current to or discharge current from a loop filter. The paths between current sources and the loop filter are selectively activated or deactivated to enable current to flow from the current source(s) to the loop filter. Similarly, the paths between current sinks and the loop filter are selectively activated or deactivated to enable current to flow from the loop filter to the current sinks(s). Accordingly, the charge pump is adapted to provide more than one bandwidth depending on the bit levels of a select signal. The slew rate of a PLL embodying the charge pump of the present invention may thus be reduced.

In some embodiments, the charge pump includes pulse-width limiting circuitry to limit the width of the pulses received from a phase/frequency detector. Since the pulse width limiting affects only relatively large phase differences, the small-signal characteristics of the loop are unchanged. Accordingly, the slew rate of the PLL may further be reduced without changes in the open loop characteristics or losses in the phase margin.

### BRIEF DESCRIPTION OF THE DRAWINGS

FIG. 1 is a simplified block diagram of a phase locked loop, as known in the prior art.

FIG. 2 shows plots of the phase-frequency of a PLL for two different values of filter resistance, as known in the prior art.

FIG. 3 is a block diagram of a charge pump, in accordance with one embodiment of the present invention.

FIG. 4 is a block diagram of a charge pump, in accordance with another embodiment of the present invention.

FIG. 5 is an exemplary one-shot block, as known in the prior art.

FIG. 6 is a timing diagram of a number of signals associated with the charge pumps shown in FIG. 4.

FIG. 7A shows the slew rate characteristics of a PLL, as in known in the prior art.

FIGS. 7B-7D show the slew rate characteristics of a PLL, in accordance with some embodiments of the present invention.

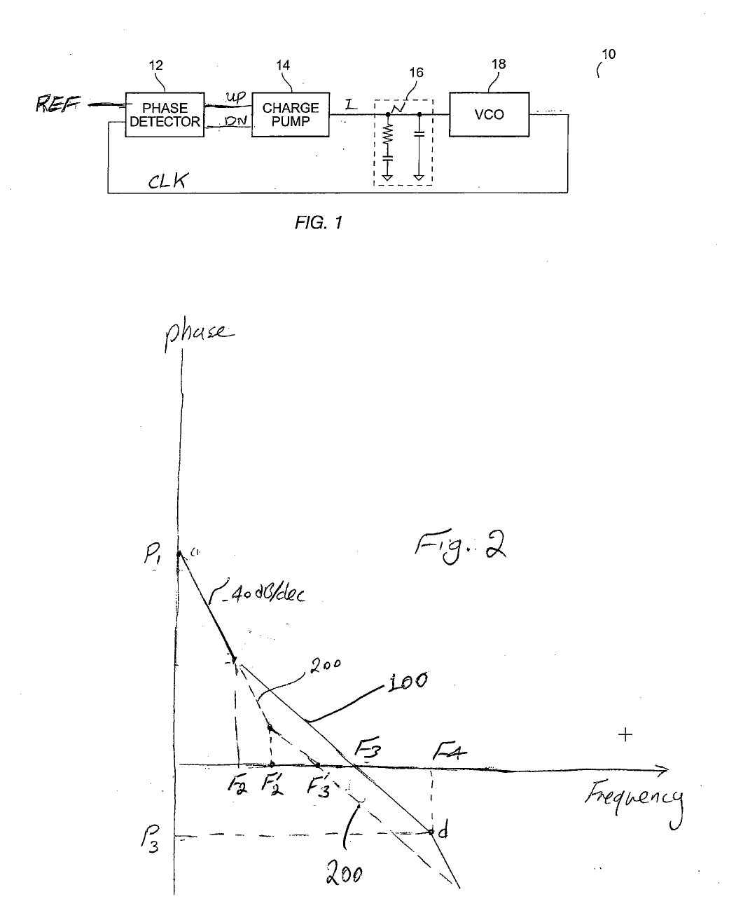

### DETAILED DESCRIPTION OF THE INVENTION

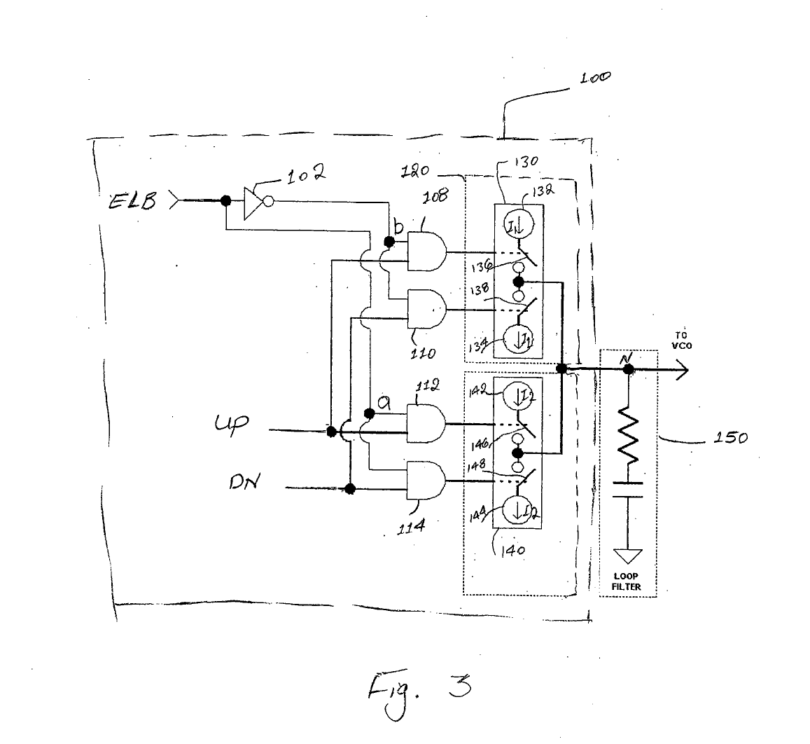

FIG. 3 is a block diagram of a charge pump 100, in accordance with one embodiment of the present invention. Charge pump 100 is shown as supplying current to or drawing current from loop filter 150. Charge pump 100 is adapted to provide two bandwidths depending on the logic level of signal ELB and as described below.

Charge pump 100 is shown as including inverter 102, logic AND gates 108, 110, 112, 114, a first current switching block 130, and a second current switching block 140. Current switching block 130 is shown as including current source 132, 134 and switches 136, 138. Similarly, current switching block 140 is shown as including current sources 142, 144 and switches 146, 148. Current sources 132 and 134 supply current I1, and current sources 142 and 144 supply current I2. Signals UP and DN are supplied by a phase/frequency detector (not shown) disposed in a phase locked loop (not shown) which also embodies charge pump 100.

If signal ELB is at a low logic level, the outputs of AND gates 112 and 114 are at a low level, therefore keeping switches 146 and 148 open. Accordingly, node N does not receive current from current source 142 and does not supply current to current source 144. Concurrently, the input terminals of AND gates 108 and 110 coupled to node B are at a high level. Accordingly, under such conditions, if signal UP is at a high level and signal DN is at a low level, switch 136 is closed and switch 138 is open, in turn, causing current source 132 to supply current to node N. If signal ELB is at a low level, signal DN is at a high level and signal UP is at a low level, switch 138 is closed and switch 136 is open, in turn, causing current source 134 to draw current from node N.

If signal ELB is at a high level, the outputs of AND gates 108 and 110 are at a low level, therefore, switches 136 and 138 are open. Accordingly, node N does not receive current from current source 132 and does not supply current to current source 134. Concurrently, the input terminals of AND gate 112, and 114 are at a high level. Accordingly, under such conditions, if signal UP is at a high level and signal DN is at a low level, switch 146 is closed and switch 148 is open, in turn, causing current source 142 to supply current to node N. If signal ELB is at a high level, signal DN is at a high level and signal UP is at a low level, switch 148 is closed and switch 146 is open, in turn, causing current source 144 to draw current from node N.

Because current I1 flowing though current sources 132 and 134 is greater than current I2 flowing through current sources 142 and 142, charge pump 100 has a higher bandwidth when signal ELB is at a low logic level. Conversely, when signal ELB is at a high logic level, charge pump 100 has a lower bandwidth. Contrary to prior art circuits, in the present invention, switching from the higher bandwidth to a relatively lower bandwidth is achieved without much effect on the phase margin stability, since the open-loop zero does not vary and only the 0 dB crossing varies. Although not shown, it is understood that if, for example, four levels of bandwidths are required, charge pump would include four current blocks each supplying or drawing one of four current levels, and signal ELB would be a 2-bit signal enabling selection of one of the four current blocks.

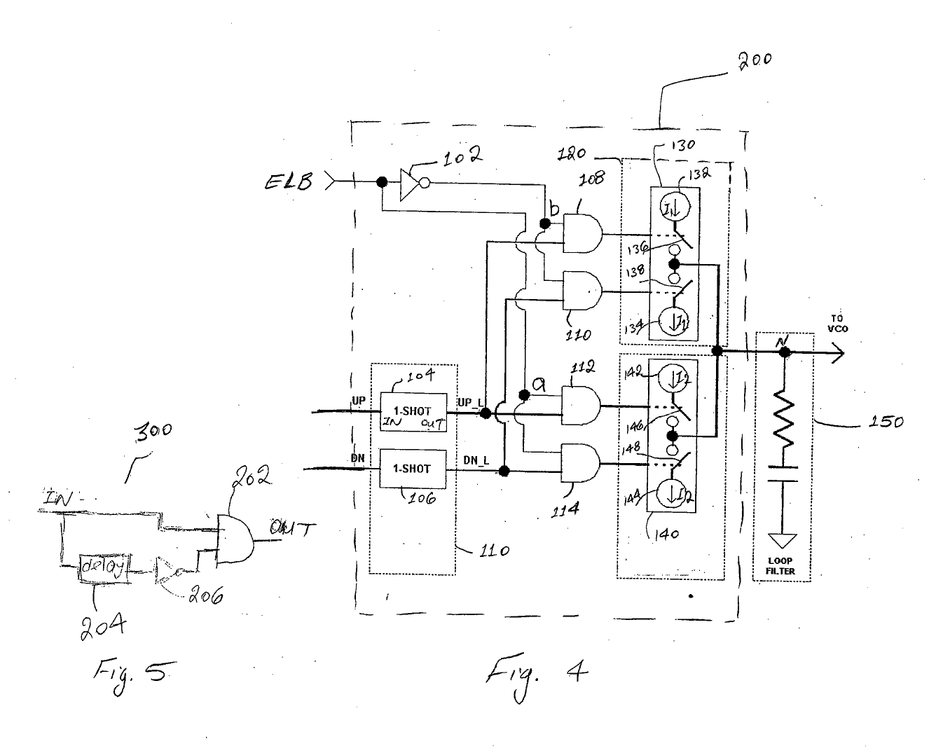

FIG. 4 is a block diagram of a charge pump 200, in accordance with another embodiment of the present invention. Charge pump 200 is similar to charge pump 100 except that charge pump 200 also includes a pulse-width limiting circuit 110. Charge pump 200 is adapted to provide two bandwidths, different from the bandwidths provided by charge pump 100, depending on the logic level of signal ELB and as described below.

In embodiment 200, the outputs of the phase detector (not shown), i.e., signals UP and DN, which control the charge pump are pulse-width limited and do not exceed a predetermined value. The charge pump delivers current only for that predetermined duration. Since the pulse width limiting affects only relatively large phase differences, the small-signal characteristics of the loop are unchanged. Accordingly, the slew rate is further reduced without changes in the open loop characteristics or losses in the phase margin. Furthermore, since the small-signal loop characteristics are unaffected by the pulse-width limiting, the pulse-width limiting may be enabled at all times if so desired. Therefore, in accordance with the present invention, either by reducing the charge pump current or limiting the pulse width, or a combination of both, the slew rate of the PLL may be reduced.

If signal ELB is at a low logic level, the outputs of AND gates 112 and 114 are at a low level, therefore keeping switches 146 and 148 open. Accordingly, node N does not receive current from current source 142 and does not supply current to current source 144. Concurrently, the input terminals of AND gates 108, and 110 coupled to node B are at a high level. Accordingly, under such conditions, if signal UP_L is at a high level and signal DN_L is at a low level, switch 136 is closed and switch 138 is open, in turn, causing current source 132 to supply current to node N. If signal ELB is at a low logic level and signal DN_L is at a high level and UP_L is low, switch 138 is closed and switch 136 is open, in turn, causing current source 134 to draw current from node N.

If signal ELB is at a high logic level, the outputs of AND gates 108 and 110 are at a low level, therefore, switches 136 and 138 are open. Accordingly, node N does not receive current from current source 132 and does not supply current to current source 134. Concurrently, the input terminals of AND gate 112, 114 are at a high level. Accordingly, under such conditions, if signal UP_L is at a high level and signal DN_L is at a low level, switch 146 is closed and switch 148 is open, in turn, causing current source 142 to supply current to node N. If signal ELB is at a high level, signal DN_L is at a high level and signal UP_L is at a low level, switch 148 is closed and switch 146 is open, in turn, causing current source 144 to draw current from node N.

Because current I1 flowing though current sources 132 and 134 is greater than current I2 flowing through current sources 142 and 142, charge pump 200 has a higher bandwidth and a higher slew rate than when signal ELB is at a low logic level. Conversely, when signal ELB is at a high logic level, charge pump 200 has a lower bandwidth and a lower slew rate. Although not shown, it is understood that if, for example, four levels of bandwidths are required, charge pump would include four current blocks each supplying or drawing one of four current levels, and signal ELB would be a 2-bit signal enabling selection of one of the four current blocks.

As shown in FIG. 5, one-shot blocks 104 and 106 generate signals UP_L and DN_L in response to, respectively, signals UP and DN they receive from a phase/frequency detector. FIG. 5 is an example of a one-shot block 300 corresponding to one-shot blocks 104 and 106, as known in the prior art. As is seen, one-shot block 300 includes a delay element 204, inverter 206 and AND gate 202. The one-shot block 300 is adapted to generate a pulse at its output upon receiving a transition at its input. Signal IN is also applied to delay element 204 whose output signal is inverted and applied to the other input terminal of AND gate 202. When a low-to high transition occurs on input signal IN, output signal OUT goes high until this transition causes a corresponding high-to-low transition at the output of inverter 206, which in turn, forces output signal OUT to a low level.

FIG. 6 is a timing diagram of a number of signals associated with charge pump 200. In FIG. 6, the reference clock signal Ref is shown as making a low-to-high transition at time T1 which leads a similar transition at time T2 of the feedback clock signal Clk. In response to the rising edge of signal Clk, signal DN is asserted and makes a low-to-high transition shortly after time T1. Signal DN remains high until it is deasserted in response to the rising edge of signal Clk. In response to the rising edge of signal Clk, signal UP is also asserted and remains active for a short time period. The low-to-high transitions of signal DN cause pulses DN_L to appear at the output of one-shot block 106. Since signal UP pulses have a relatively narrow width, signal UP_L pulses also have relatively short durations and are narrow.

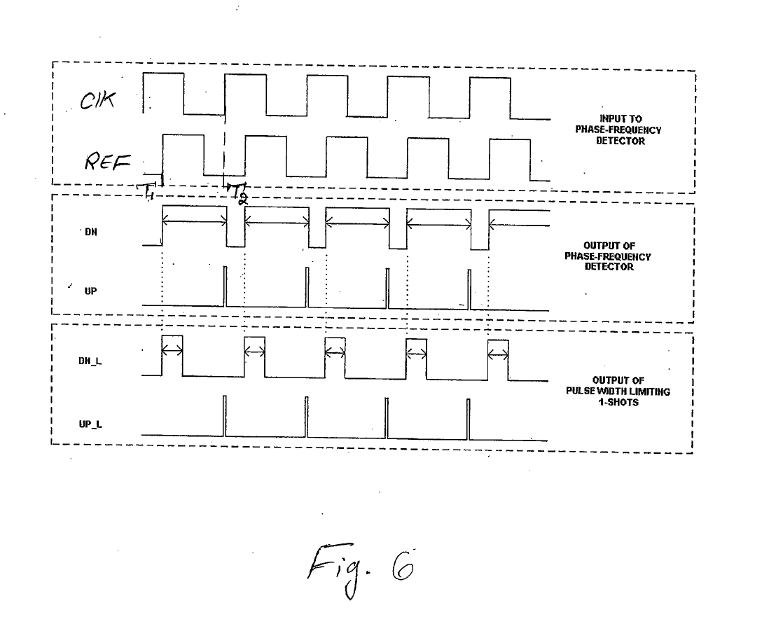

FIG. 7A shows the slew rate characteristics of a PLL, as in known in the prior art. In FIG. 7A, the PLL has a slew rate of 459 picoseconds/cycle. FIG. 7B show the slew rate characteristics of PLL 200 when signal ELB is selected to have a high logic level, i.e., when the low-bandwidth mode is disabled but and there is pulse width limiting. In FIG. 7B, the PLL has a slew rate of 348 psec/cycle. FIG. 7C shows the slew rate of characteristics of PLL 100 when signal ELB is selected to have a low logic level, i.e., when the low-bandwidth mode is enabled but there is no pulse width limiting. In FIG. 7C, the PLL has a slew rate of 135 psec/cycle. FIG. 7D shows the slew rate of characteristics of PLL 200 when signal ELB is selected to have a low logic level, i.e., when the low-bandwidth mode is enabled and there is pulse width limiting. In FIG. 7D, the PLL has a slew rate of 92 psec/cycle.

The above embodiments of the present invention are illustrative and not limiting. Various alternatives and equivalents are possible. The invention is not limited by the type of current source, switch or the loop filter. The invention is not limited by the number of current sources or current sinks. The invention is not limited by the type of integrated circuit in which the present disclosure may be disposed. Nor is the disclosure limited to any specific type of process technology, e.g., CMOS, Bipolar, or BICMOS that may be used to manufacture the present disclosure. Other additions, subtractions or modifications are obvious in view of the present disclosure and are intended to fall within the scope of the appended claims.

What is claimed is:

1. A charge pump comprising:
a first current switching block comprising:
first and second current sources;
a first switch adapted to cause the first current source to supply a first current to the loop filter in response to a first signal; and
a second switch adapted to cause the second current source to draw the first current from the loop filter in response to a second signal;
a second current switching block comprising:
third and fourth current sources;
a third switch adapted to cause the second current source to supply a second current to the loop filter in response to a third signal; and
a fourth switch adapted to cause the second current source to draw the second current from the loop filter in response to a fourth signal; wherein said first current is different from said second current; and
a control block responsive to a detector's output and to supply the first, second, third and fourth signals.

2. The charge pump of claim 1 wherein said control block further comprises a plurality of combinatorial logic blocks configured to receive a bandwidth select signal.

3. The charge pump of claim 1 wherein said control block further comprises a pulse width limiting block.

4. The charge pump of claim 3 wherein said pulse width limiting block further comprises first and second one-shot blocks.

5. A method of controlling a slew rate of a phase locked loop, the method comprising:
supplying a first current to a loop filter in response to a first signal;
drawing the first current from the loop filter in response to a second signal;
supplying a second current to the loop filter in response to a third signal; and
drawing the second current from the loop filter in response to a fourth signal;
wherein the first current is different from the second current.

6. The method of claim 5 further comprising:
limiting a pulse width of a fifth signal used to generated the first and third signals.

7. The method of claim 6 further comprising:
limiting a pulse width of a sixth signal used to generated the second and fourth signals.

8. The method of claim 7 wherein said fifth and sixth signal are generated in response to comparing a phase of a reference clock to a phase of a generated clock.

9. The method of claim 7 wherein said fifth and sixth signal are generated in response to comparing a frequency of a reference clock to a frequency of a generated clock.

10. The method of claim 7 wherein the pulse widths of the fifth and sixth signals are limited using one-shot blocks.
